(19) United States
(12) Patent Application Publication
(10) Pub. No.: US 2004/0201506 A1
(43) Pub. Date: Oct. 14, 2004

(54) The Set Side Box

(76) Inventor: Tianmo Lei, Santa Clara, CA (US)

Correspondence Address: TIANMO LEI, 775 ENRIGHT AVE., SANTA CLARA, CA, 95050, US

(21) Appl. No.: 10/249,450

(22) Filed: Apr. 10, 2003

(51) Int. Cl. H03M 1/00

(52) U.S. Cl. 341/110

(57) ABSTRACT

A computer controlled data acquisition device for connection to a computing device includes a high speed serial port for connecting to the computing device, an A/D and D/A converter coupled to the serial port, a processor coupled to the serial port and to the A/D and D/A converter, an adaptor coupled to the A/D and D/A converter and to the processor, a detector for detecting data coupled to the adaptor, and an output controller coupled to the adaptor.

### BACKGROUND OF INVENTION

The ability of personal computer (PC) is far beyond the “computing” as its name indicated. Its applications in business, industry, entertainment, etc are well known. With the rapid developments in the speed of processor and the sizes of memory and storage, its potential power in daily life will never be under-estimated.

Due to the historical reasons, the measurement instruments, detection apparatus, control equipments and consumer applicants have their own unique data processing computing, input device and audio-video output components. They do not take advantage of powerful abilities of PC.

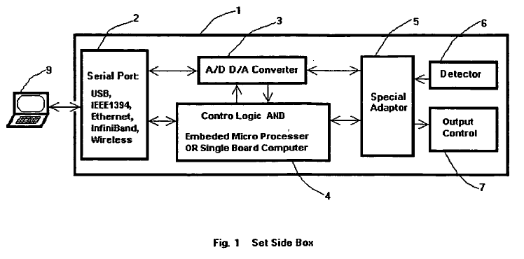

In the digital age, modernized equipment is digitized. The novel invention is that 1) separating data acquisition part and output control part, 2) digitizing input signal via A/D and embedded microprocessor, c) integrating the digitized data with PC through high speed serial port. These three operations are implemented by the Set Side Box (SSB) shown in FIG. 1. All resources of PC are fully employed which include precise computation, audio-video output, Internet access, database, etc. Products like oscilloscope and signal test equipment, environmental (air, water and noise) quality monitor, ultrasonic equipment, even robot, with SSP-PC structure, will appear at consumer market. Longport, Inc″s LDS is a good example (http://www.longportinc.com).

PC is also known as “electronic brain”. Using SSB to integrate various detector and output control with PC through high speed serial port is similar to adding the eye, nose, ear and hand, foot to the brain. It will go a step further to release talent energy of the brain.

To achieve this objective, high-speed digital connection between PC and data acquisition part and output control part is necessary. The rapid developments of semiconductor industry and emerge of new generation of PC, including high speed CPU, memory and storage, high speed serial port and communication protocol (Ethernet, USB, IEEE1394, InfiniBand and Wireless communication) make this invention become true.

The Windows interface of PC is well known by its users. New instrument and equipment with Windows will be very user friendly. PC communication ability and database resource will further improve the performance and function of new instrument and equipment with the attached SSB.

### SUMMARY OF INVENTION

The present invention disclosed a versatile SSB. While connected with PC, it will create cost effective digitized equipment. The display device, the digital processing engine, and the control elements of the original equipment will be replaced by the monitor, motherboard, input device (keyboard, mouse, joystick) of PC, respectively.

The present invention can be used in business, industry, agriculture, geology, military, and clinics for the routine use. Some similar efforts have been done: U.S. Pat. No. 6,073,045; U.S. Pat. No. 6,182,497; U.S. Pat. No. 6,111,929; U.S. Pat. No. 6,035,263; U.S. Pat. No. 5,394,237; U.S. Pat. No. 5,220,522; U.S. Pat. No. 6,129,665; U.S. Pat. No. 6,526,163.

### DETAILED DESCRIPTION

FIG. 1 shows the SSB 1. From left to right, the high-speed serial port 2 provides an easy digital connection to PC 9. A/D and/or D/A converter 3, the corresponding control logic and the embedded microprocessor or single board computer 4 perform the transform between Analog signal and digital data and the pre-processing of the data. The special adaptor 5 connects these digital/analog conversion parts 3, 4 to different detector 6 and output control 7, using analog filter, amplifier, driver and controller. The detector 6 can be any sensitive device including sound, light, electric, magnetic, heat, chemical, force, movement and physiological sensitive component. The output control 7 can be any output of sound, light, electric, magnetic, heat, or step motor, mechanical arm/foot and other machine.

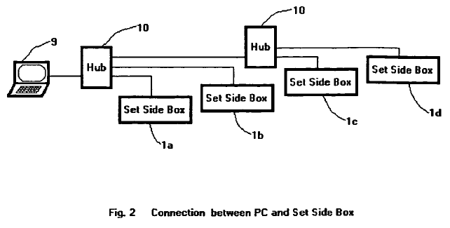

FIG. 2 shows a tree structure of connection between SSB and PC. Several SSBs are connected to PC 9 via Hub 10. Each SSB has the similar structure as shown in FIG. 1. The serial port of the SSB is connected to serial port of the PC 9 or Hub 10. The Hub can be Ethernet hub, USB hub, IEEE1394 hub, InfiniBand hub or wireless communication hub. In FIG. 2, PC receives radio signal of GPS from SSB 1a to locate the position; or work as an oscilloscope with SSB 1b; or use ultrasonic transducer SSB 1c to emit and receive ultrasound beam for diagnostic or treatment, or controls mechanical arm using SSB 1d.

1. (Cancelled)

2. (Cancelled)

3. (Cancelled)

4. A computer controlled data acquisition device for connection to a computing device comprising:
a high speed serial port for connecting to the computing device;
an A/D and D/A converter coupled to the serial port;
a processor coupled to the serial port and to the A/D and D/A converter;
an adaptor coupled to the A/D and D/A converter and to the processor;
a detector for detecting data coupled to the adaptor; and
an output controller coupled to the adaptor.

5. The computer controlled data acquisition device for connection to a computing device of claim 4, wherein detected data is pre-processed in the processor.

6. The computer controlled data acquisition device for connection to a computing device of claim 4, wherein the processor comprises control logic.

7. The computer controlled data acquisition device for connection to a computing device of claim 4, wherein the adaptor comprises an analog filter coupled to an amplifier coupled to a driver, and coupled to a controller.

8. The computer controlled data acquisition device for connection to a computing device of claim 4, wherein the detector comprises a sound sensitive component.

9. The computer controlled data acquisition device for connection to a computing device of claim 4, wherein the detector comprises a light sensitive component.

10. The computer controlled data acquisition device for connection to a computing device of claim 4, wherein the detector comprises a electrically sensitive component.

11. The computer controlled data acquisition device for connection to a computing device of claim 4, wherein the detector comprises a magnetically sensitive component.

12. The computer controlled data acquisition device for connection to a computing device of claim 4, wherein the detector comprises a heat sensitive component.

13. The computer controlled data acquisition device for connection to a computing device of claim 4, wherein the detector comprises a chemically sensitive component.

14. The computer controlled data acquisition device for connection to a computing device of claim 4, wherein the detector comprises a force sensitive component.

15. The computer controlled data acquisition device for connection to a computing device of claim 4, wherein the detector comprises a movement sensitive component.

16. The computer controlled data acquisition device for connection to a computing device of claim 4, wherein the detector comprises a physiologically sensitive component.

17. The computer controlled data acquisition device for connection to a computing device of claim 4, wherein the computing device comprises a Windows interface.

18. The computer controlled data acquisition device for connection to a computing device of claim 4, wherein the computer controlled data acquisition device is coupled to the computing device through a hub in a tree structure.

19. The computer controlled data acquisition device for connection to a computing device of claim 4, wherein the computing device comprises a database program operating on the computing device.

20. The computer controlled data acquisition device for connection to a computing device of claim 4, wherein the output controller comprises a machine.

21. A computer controlled data acquisition device for connection to a computing device comprising:
a high speed serial port for connecting to the computing device;
an A/D and D/A converter coupled to the serial port;
a processor coupled to the serial port and to the A/D and D/A converter, the processor comprising control logic;
an adaptor coupled to the A/D and D/A converter and to the processor;
a detector for detecting data coupled to the adaptor, the processor operable to pre-process detected data; and
an output controller coupled to the adaptor, the output controller comprising a machine.
